(19) United States
(12) Patent Application Publication
(10) Pub. No.: US 2024/0319259 A1
(43) Pub. Date: Sep. 26, 2024

(54) ELECTRICAL DEVICE RELIABILITY PROPERTIES PREDICTION DEVICE AND ELECTRICAL DEVICE RELIABILITY PROPERTIES PREDICTION METHOD

(71) Applicant: SAMSUNG ELECTRONICS CO., LTD., Suwon-si (KR)

(72) Inventors: Minseok KIM, Suwon-si (KR); Taesin KWAG, Suwon-si (KR); Yeonjeong KIM, Suwon-si (KR); Hyungkeun YOO, Suwon-si (KR); Jongchul KIM, Suwon-si (KR); Kyunghoon LEE, Suwon-si (KR)

(73) Assignee: SAMSUNG ELECTRONICS CO., LTD., Suwon-si (KR)

(21) Appl. No.: 18/608,292

(22) Filed: Mar. 18, 2024

(30) Foreign Application Priority Data
Mar. 20, 2023 (KR) 10-2023-0036158

(51) Int. Cl. G01R 31/28; G06F 30/367; G06T 7/00

(52) U.S. Cl. CPC G01R 31/2831; G06F 30/367; G06T 7/0004; G06T 2207/30148

(57) ABSTRACT

Provided is an electrical reliability properties prediction method including generating a plurality of pieces of optical spectrum data of a substrate, performing a wafer level reliability (WLR) process on the substrate, measuring electrical reliability property data based on the WLR process, matching an inspection region to the plurality of pieces of optical spectrum data and the electrical reliability property data, generating a data set, performing data pre-processing, training an electrical reliability properties prediction model, acquiring a plurality of pieces of target optical data from a database, and extracting, with respect to the plurality of pieces of target optical data, a feature vector from the plurality of pieces of target optical data, and detecting predicted electrical reliability property data of the plurality of pieces of target optical data based on the feature vector.

### CROSS-REFERENCE TO RELATED APPLICATION

This application is based on and claims priority under 35 U.S.C. § 119 to Korean Patent Application No. 10-2023-0036158, filed on Mar. 20, 2023, in the Korean Intellectual Property Office, the disclosure of which is incorporated by reference herein in its entirety.

### BACKGROUND

Embodiments are related to predicting reliability properties of an electrical device based on optical data.

A semiconductor process draws circuit patterns on a silicon substrate. As the degree of integration of the semiconductor process increases and the line width becomes finer, the difficulty of production increases. In order to optimize process conditions, it is essential to determine whether or not to improve process conditions by verifying the electrical reliability properties of semiconductor devices before shipment. Thus, if the electrical reliability properties of semiconductor devices can be predicted early to minimize the development period required for optimizing process conditions, productivity can be greatly improved. For this reason, techniques for predicting electrical reliability properties of semiconductor devices are being studied. One of these techniques is a technique of predicting electrical device reliability properties by using optical spectrum data of a pattern transferred to a substrate.

### SUMMARY

Embodiments provide an electrical reliability properties prediction device and an electrical reliability properties prediction method, whereby defects of a pattern transferred to a substrate may be predicted in advance based on optical data.

In addition, the objective to be solved by embodiments is not limited to the above-mentioned objectives, and other objectives can be clearly understood by those skilled in the art from the description below.

Provided herein is an electrical reliability properties prediction method including generating a plurality of pieces of optical spectrum data of a substrate, performing a wafer level reliability (WLR) process on the substrate, measuring electrical reliability property data based on the WLR process, matching an inspection region to the plurality of pieces of optical spectrum data and the electrical reliability property data based on the plurality of pieces of optical spectrum data and the electrical reliability property data, generating a data set including at least four pieces of optical data among the plurality of pieces of optical spectrum data and the electrical reliability property data, performing data pre-processing on the data set to extract a data sample, training an electrical reliability properties prediction model by using predicted electrical reliability property data as an output value and the data sample, as an input value, acquiring a plurality of pieces of target optical data from a database, and extracting, with respect to the plurality of pieces of target optical data, a feature vector from the plurality of pieces of target optical data by using the electrical reliability properties prediction model, and detecting predicted electrical reliability property data of the plurality of pieces of target optical data based on the feature vector.

Also provided herein is an electrical reliability properties prediction method including requesting optical data from a server, acquiring a spectral image of a substrate based on the requesting, and extracting a plurality of pieces of optical spectrum data from the spectral image, performing a WLR process on the substrate, measuring electrical reliability property data based on the WLR process, matching an inspection region to the plurality of pieces of optical spectrum data and the electrical reliability property data based on the plurality of pieces of optical spectrum data and the electrical reliability property data, generating a data set including at least four pieces of optical data among the plurality of pieces of optical spectrum data and the electrical reliability property data, performing data pre-processing on the data set to obtain a data sample, training an electrical reliability properties prediction model by using predicted electrical reliability property data as an output value and the data sample, as an input value, acquiring a plurality of pieces of target optical data from a database, and extracting, with respect to the plurality of pieces of target optical data, a feature vector from the plurality of pieces of target optical data by using the electrical reliability properties prediction model, and detecting predicted electrical reliability property data of the plurality of pieces of target optical data based on the feature vector, wherein the electrical reliability properties prediction model uses a neural network learning method of Feed-Forward Neural Networks (FFNN).

Also provided herein is an electrical reliability properties prediction device including a substrate inspection device configured to acquire a spectral image of a substrate according to a request from a server and extract a plurality of pieces of optical spectrum data from the spectral image, a database storing a plurality of pieces of target optical data, the plurality of pieces of optical spectrum data, and electrical reliability property data of the substrate, the server storing a program including one or more instructions and executing the one or more instructions of the program, a data matching unit configured to match an inspection region to the plurality of pieces of optical spectrum data and the electrical reliability property data based on the plurality of pieces of optical spectrum data and the electrical reliability property data and generate a data set including at least four pieces of optical data among the plurality of pieces of optical spectrum data and the electrical reliability property data, a data pre-processing unit configured to perform data pre-processing on the data set, and an electrical reliability properties prediction module configured to train an electrical reliability properties prediction model by using predicted electrical reliability property data as an output value and the data set on which the data pre-processing has been performed, as an input value, and predict, based on the plurality of pieces of target optical data, electrical reliability for defects of the substrate.

### BRIEF DESCRIPTION OF THE DRAWINGS

Embodiments will be more clearly understood from the following detailed description taken in conjunction with the accompanying drawings in which:

FIG. 1 is a schematic diagram for describing spectral ellipsometry;

FIG. 2 is a conceptual diagram illustrating a substrate inspection device according to embodiments;

FIG. 3 is a block diagram illustrating an electrical reliability properties prediction device according to an embodiment;

FIGS. 4A and 4B are flowcharts of an electrical reliability properties prediction method according to an embodiment;

FIGS. 5A to 5D are diagrams illustrating measurement regions of optical data according to embodiments;

FIG. 6 is a diagram showing electrical reliability property data of a substrate according to an embodiment;

FIGS. 7A to 7D are graphs showing optical data according to embodiments;

FIG. 8 is a conceptual diagram illustrating a data classification method of an electrical reliability properties prediction method, according to an embodiment;

FIG. 9 is a conceptual diagram for describing an electrical reliability properties prediction model according to an embodiment;

FIG. 10 is a graph showing consistency of an electrical reliability properties prediction model according to an embodiment; and

FIG. 11 is a graph showing effects of an electrical reliability properties prediction device and an electrical reliability properties prediction method, according to an embodiment.

### DETAILED DESCRIPTION OF THE EMBODIMENTS

Hereinafter, embodiments will be described in detail with reference to the accompanying drawings. The same reference numerals are used for the same components in the drawings, and repeated descriptions thereof are omitted.

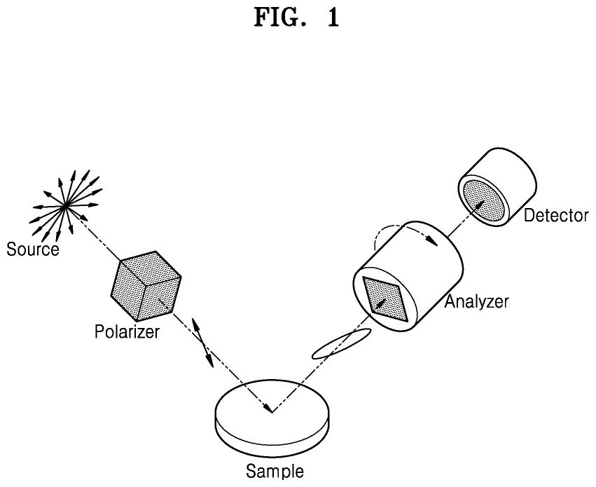

FIG. 1 is a schematic diagram for describing spectral ellipsometry.

Referring to FIG. 1, spectral ellipsometry is an optical technique for examining structural properties such as the thickness of a thin film and the line width of a pattern formed on the thin film, and dielectric properties such as complex refractive index and dielectric function. The composition, roughness, thickness, depth, crystalline properties, doping concentration, electrical conductivity, or the like, of thin films included in a sample to be inspected may be characterized by spectral ellipsometry.

Spectral ellipsometry is a technique for determining the characteristics of a thin film by comparing changes in polarization before/after interaction with a thin film, such as reflection and transmission, with a model. Here, changes in polarization may be expressed by an amplitude ratio Ψ ′ and a phase difference Δ. An amplitude ratio refers to a ratio of an amplitude of a p-wave to an amplitude of an s-wave when light is reflected from a thin film. A phase difference refers to the difference in phase changes between a p-wave and an s-wave when light is reflected from a thin film. Changes in polarization depend on the type and thickness of materials constituting a thin film, and thus, allow measuring the thickness and optical constants of all types of films in a non-contact manner. Spectral ellipsometry allows high-precision characterization of single atomic layers, and monolayers or multilayers with thicknesses ranging from several angstroms to several micrometers.

As illustrated in FIG. 1, unpolarized electromagnetic radiation emitted by a light source may be linearly polarized through a polarizer. Selectively, a compensator such as a retarder or a quarter (¼) wave plate may be further disposed on an optical path between a polarizer and a sample.

Radiation reflected from the sample may reach a detector after passing through a second polarizer, commonly referred to as an analyzer. Similarly, a second compensator may be arranged in an optical path between the analyzer and the sample.

The spectroscopic ellipsometry is a specular optical inspection method in which the angle of incidence and the angle of reflection are the same, wherein an incident beam and a reflected beam extend over a plane of incidence. Polarization in a direction parallel to the plane of incidence is called p-polarization, and polarization in a direction perpendicular to the p-polarization is called s-polarization.

According to spectral ellipsometry, a complex reflectance ρ, which may be expressed based on the reflection amplitude ratio Ψ and the phase difference Δ, is measured. A polarization state of light incident on the sample may be decomposed into s and p components. Amplitudes of the s and p components after reflection, which are normalized to initial values, are denoted as rs and rp, respectively, below. Here, rs, rp, and the complex reflectance p satisfy Equation 1 below.

$$ρ = \frac{rp}{rs} = tan Ψ \cdot {e}^{i Δ} \qquad [ Equation 1 ]$$

The difference between rp and rs may be maximized by selecting an angle of incidence of light to be close to the Brewster angle of the sample. In spectral ellipsometry, a ratio (or difference) between two values is measured, thus providing precise and highly reproducible measurement results. Accordingly, spectral ellipsometry has advantages in that spectral ellipsometry is relatively insensitive to light scattering and variations in inspection conditions and does not require a separate standard sample and reference beam.

Except for exceptionally simple cases such as infinite-thick films or homogeneous films, the measured reflection amplitude ratio Ψ ′ and the measured phase difference Δ cannot be directly converted into optical constants of the sample. Thus, in general, model analysis may be performed to acquire optical constants from the results of spectral ellipsometry. An example of the model is a Forouhi Bloomer model. A model may be based on physical energy transfers or free parameters for data fitting. The model may include a stacking order of layers included in a sample, an optical constant (e.g., a refractive index or dielectric function tensor) of each of individual layers, and a thickness parameter.

In spectral ellipsometry, the reflection amplitude ratio Ψ and the phase difference Δ may be measured using iterations (e.g., method of least squares) for varying optical constants and/or thickness parameters. A Fresnel equation may be used to calculate the reflection amplitude ratio Ψ and the phase difference Δ. When the calculated values of the reflection amplitude ratio Ψ and the phase difference Δ are consistent with experimental data, optical constants and thickness values of thin films corresponding thereto may be determined as optical constants and thicknesses of thin films included in the sample.

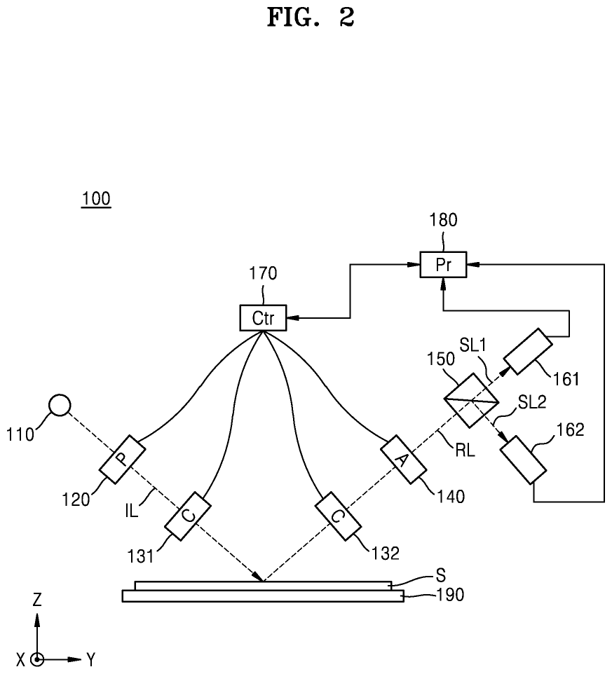

FIG. 2 is a conceptual diagram illustrating a substrate inspection device according to embodiments.

Referring to FIG. 2, a substrate inspection device 100 may include a light source 110, a polarizer 120, first and second compensators 131 and 132, an analyzer 140, a light splitting element 150, first and second detectors 161 and 162, a controller 170, a processor 180, and a tray 190. The substrate inspection device 100 may inspect a substrate S on which a series of semiconductor device manufacturing processes have been performed. The substrate inspection device 100 may be a spectral ellipsometer capable of performing spectral ellipsometry described above.

The substrate S may be disposed on the tray 190. The tray 190 may support and fix the substrate S during a semiconductor process and inspection. The tray 190 may move the substrate S to a required position according to inspection and process execution. A direction perpendicular to an upper surface of the substrate S disposed on the tray 190 is referred to as a Z-direction, and two directions parallel to the upper surface and orthogonal to each other are referred to as a X-direction and a Y-direction. For example, the tray 190 may move the substrate S in the X- and Y-directions so that different portions of the substrate S may be inspected. The tray 190 may move the substrate S in the Z-direction such that an optical system included in the substrate inspection device 100 is focused on the substrate S.

The substrate S may include, for example, silicon (Si). The substrate S may include a semiconductor element such as germanium (Ge) or a compound semiconductor such as silicon carbide (SiC), gallium arsenide (GaAs), indium arsenide (InAs), and indium phosphide (InP). According to some embodiments, the substrate S may have a silicon on insulator (SOI) structure. The substrate S may include a buried oxide layer. According to some embodiments, the substrate S may include a conductive region, for example, a well doped with impurities. According to some embodiments, the substrate S may have various device isolation structures such as shallow trench isolation (STI) that separates the doped wells from each other.

The substrate S may be a wafer on which a semiconductor process for manufacturing semiconductor devices has been performed. A process of forming a semiconductor device may include: i) an oxidation process to form an oxide film; ii) a lithography process including spin coating, exposure, and development; iii) a thin film deposition process; iv) a dry or wet etching process; and v) a metal wiring process or the like.

The oxidation process is a process of forming a thin and homogeneous silicon oxide film by chemically reacting oxygen or water vapor with a surface of a silicon substrate at a high temperature of about 800 degrees to about 1200 degrees. The oxidation process may include dry oxidation and wet oxidation. In dry oxidation, an oxide film may be formed by reacting with oxygen gas, and in wet oxidation, an oxide film may be formed by reacting oxygen with water vapor.

According to some embodiments, an SOI structure may be formed on a substrate by an oxidation process. The substrate may also include a buried oxide layer. According to some embodiments, the substrate may have various device isolation structures such as STI.

The lithography process is a process of transferring a circuit pattern previously formed on a lithography mask, to a substrate through exposure. The lithography process may be performed in the order of spin coating, exposure, and development processes.

The thin film deposition process may be one of, for example, atomic layer deposition (ALD), chemical vapor deposition (CVD), plasma-enhanced CVD (PECVD), metal organic CVD (MOCVD), physical vapor deposition (PVD), reactive pulsed laser deposition, molecular beam epitaxy, and direct current (DC) magnetron sputtering.

The dry etching process may be, for example, any one of reactive ion etching (RIE), deep RIE (DRIE), ion beam etching (IBE), and Ar milling. As another example, the dry etching process that may be performed on the substrate S may be atomic layer etching (ALE). In addition, the wet etching process that may be performed on the substrate S may be an etching process in which at least one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂, and COS is used as an etchant gas.

The metal wiring process may be a process of forming a conductive wiring (metal line) to implement a circuit pattern for operation of a semiconductor device. Through the metal wiring process, transmission paths of ground, power, and signals for operating semiconductor devices may be formed. A metal wiring may include gold, platinum, silver, aluminum, and tungsten.

According to some embodiments, in the process of forming a semiconductor device, a planarization process such as a chemical mechanical polish (CMP) process, an ion implantation process, and the like may be further performed.

The substrate inspection device 100 may inspect layers and patterns formed on the substrate S by at least one of the processes described above. The substrate inspection device 100 may determine any one of the thickness of a formed layer, a critical dimension of a pattern formed on the layer, the height of a pattern, a recess, an overlay, and a defect. Here, overlay is a quantity indicating the degree of misalignment between the already formed underlying layer and a photoresist pattern.

The light source 110 may generate incident light IL and emit the generated incident light IL toward the substrate S. The incident light IL generated by the light source 110 may be unpolarized light. However, embodiments are not limited thereto, and the incident light IL may be polarized light. The incident light IL may be incident in a direction inclined with respect to the upper surface of the substrate S.

A wavelength of the incident light IL may be in a wavelength band within a set range. According to some embodiments, the incident light IL may be visible light. According to some embodiments, the wavelength of the incident light IL may be about 400 nm to about 800 nm. According to some other embodiments, the incident light IL may be near infrared rays or infrared rays. According to some embodiments, a wavelength band of the incident light IL may be about 800 nm to about 3000 nm. The light source 110 may emit light of a specific wavelength or simultaneously emit light of several wavelengths. The light source 110 may emit light of different wavelengths according to time.

The polarizer 120 may be disposed on a path of the incident light IL between the light source 110 and the substrate S. The polarizer 120 may determine a polarization direction of the incident light IL. The incident light IL that has passed through the polarizer 120 may include only the same component as the polarization direction of the polarizer 120. Accordingly, the incident light IL passing through the polarizer 120 may be linearly polarized. The first compensator 131 may be disposed on a path of the incident light IL between the polarizer 120 and the substrate S.

Reflected light RL reflected by the substrate S may reach the light splitting element 150. The second compensator 132 and the analyzer 140 may be disposed on an optical path between the light splitting element 150 and the substrate S.

In some cases, either of the first and second compensators 131 and 132 may be omitted. The first compensator 131 may adjust the phase difference Δ of the incident light IL. The second compensator 132 may adjust the phase difference Δ of the reflected light RL.

The analyzer 140 may adjust a polarization direction of the reflected light RL reflected from the substrate S. In some cases, an imaging lens may be further disposed on an optical path of the reflected light RL (for example, between the analyzer 140 and the light splitting element 150). The imaging lens may adjust chromatic aberration of the reflected light RL.

At least one of the polarizer 120, the first and second compensators 131 and 132, and the analyzer 140 may be connected to a rotation driver capable of adjusting a polarization direction.

A rotation driver (e.g., a step motor) connected to at least one of the polarizer 120, the first and second compensators 131 and 132, and the analyzer 140 may be connected to the controller 170. The rotation driver may be controlled by the controller 170. Accordingly, rotation of at least one of the polarizer 120, the first and second compensators 131 and 132, and the analyzer 140 may be controlled by the controller 170 at a set speed.

Light passing through the analyzer 140 may reach the light splitting element 150. The light splitting element 150 may be a prism formed by processing a translucent material such as quartz. The light splitting element 150 may split the reflected light RL of a single path into a plurality of paths. The light splitting element 150 may generate first split light SL1 and second split light SL2. FIG. 2 illustrates that the first split light SL1, which is transmitted light, is detected by the first detector 161, and the second split light SL2, which is reflected light, is detected by the second detector 162, but the opposite case is also possible.

The first split light SL1 and second split light SL2 split by the light splitting element 150 may reach the first and second detectors 161 and 162, respectively. The first and second detectors 161 and 162 may be any one of a charge-coupled device (CCD) camera and a complementary metal-oxide-semiconductor (CMOS) image sensor. According to some embodiments, the first and second detectors 161 and 162 may be, for example, spectral imaging cameras but are not limited thereto. The first and second detectors 161 and 162 may detect a spectral image of portions por of the substrate S. Signals generated by the first and second detectors 161 and 162 may be transferred to the processor 180. The size ratio between the first split light SL1 and second split light SL2 may be 5:5 but is not limited thereto.

Thus, the first and second detectors 161 and 162 may respectively detect the first split light SL1 and second split light SL2 split from the reflected light RL reflected on the same portion por on the substrate S.

The first and second detectors 161 and 162 may generate electrical signals (e.g., spectral images) based on detection results of the first split light SL1 and second split light SL2. Methods whereby the first and second detectors 161 and 162 generate electrical signals (e.g., spectral images) may be different from each other. The first detector 161 may be a chopping mode detector. The second detector 162 may be a continuous mode detector. The first detector 161 may generate an electrical signal (e.g., a spectral image) corresponding to a certain point in time (i.e., a very short time section) or a certain rotation angle. The first detector 161 may generate a section average of electrical signals (e.g., spectral images) corresponding to a certain continuous time section or a certain rotation angle range.

Points in time at which the first and second detectors 161 and 162 sample the reflected light RL may be different from each other. In other words, the first and second detectors 161 and 162 may receive the first split light SL1 and second split light SL2 split from the reflected light RL reflected by the same portion por on the substrate S and generate a signal based on light arriving at different points in time. Also, the first and second detectors 161 and 162 may be connected to a certain driving device. Accordingly, the first and second detectors 161 and 162 may move along optical paths of the first split light SL1 and second split light SL2, respectively.

According to some embodiments, the processor 180 may include at least one of a data analyzer and an optical critical dimension (OCD) instrument including a spectrum recognition algorithm. Here, the OCD instrument may be a device for extracting physical parameters of the substrate S from spectrum data. The spectral recognition algorithm of the OCD instrument may use a rigorous coupled-wave analysis (RCWA) algorithm. The RCWA algorithm may be usefully used to describe the diffraction or reflection of electromagnetic waves from a surface of a grating structure. However, embodiments are not limited thereto, and to monitor the profile change tendency in the substrate S, the processor 180 may use any one of a spectral image spectral ellipsometric polarization analysis algorithm and a multi-point high-speed measurement spectral ellipsometric polarization analysis algorithm. Also, the processor 180 may use a variable separation algorithm such as a correlation analysis algorithm, a principal component analysis algorithm, or a rank test for extracting a profile change value from multiple spectra.

According to some embodiments, the processor 180 may determine a first angle θ1 or a first time t1 of the first detector 161 that reacts most sensitively to a measurement variable to be measured by the substrate inspection device 100. According to some embodiments, the processor 180 may determine a measurement angle range or a first time section of the second detector 162 that reacts most sensitively to a measurement variable to be measured by the substrate inspection device 100.

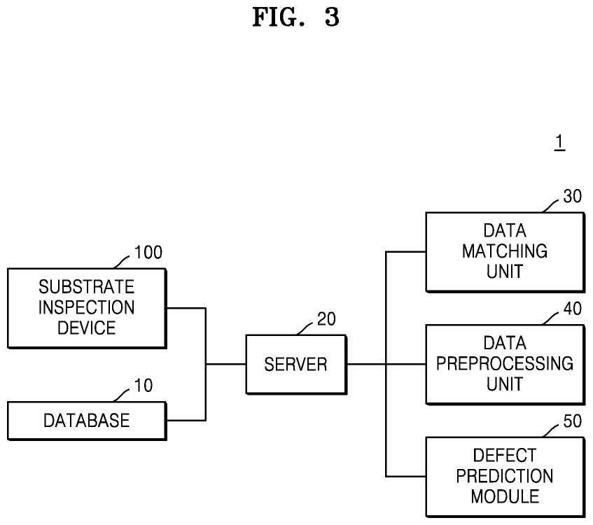

FIG. 3 is a block diagram illustrating an electrical reliability properties prediction device 1 according to an embodiment.

Referring to FIG. 3, the electrical reliability properties prediction device 1 may include the substrate inspection device 100, a database 10, a server 20, a data matching unit 30, a data pre-processing unit 40, and an electrical reliability properties prediction module 50. The electrical reliability properties prediction module 50 may be referred to herein as a defect prediction module.

The substrate inspection device 100 may transmit spectrum data acquired by inspecting a substrate to the server 20. The server 20 may receive spectrum data from the substrate inspection device 100 and store the same in the database 10. The server 20 may include various integrated circuit components, software elements, such as memory elements, processing elements, logic elements, and lookup elements, that may perform various functions under the control by one or more microprocessors or other control devices.

The software elements of the server 20 may be implemented with any programming or scripting language such as C, C++, C#, Java, JavaScript, JavaScript Object Notation (JSON), VBScript, Macromedia Cold Fusion, COBOL, Active Server Pages, Perl, Assembly, PHP, awk, Python, Visual Basic, SQL Stored Procedures, PL/SQL, any Unix shell script, and/or any extensible markup language (XML), with the various algorithms being implemented with any combination of data structures, objects, processes, routines, or other programming elements. The server 20 may perform various calculations by using spectrum data.

The data matching unit 30 may match an inspection region based on a plurality of pieces of optical spectrum data and electrical reliability property data and generate a data set including at least four pieces of optical data among the plurality of pieces of optical spectrum data and electrical reliability property data.

The data pre-processing unit 40 may perform data pre-processing on a data set. In detail, data pre-processing performed on a data set may refer to data processing of classifying the data set into a learning data set, a verification data set, and a test data set.

The electrical reliability properties prediction module 50 may include an electrical reliability properties prediction model. The electrical reliability properties prediction module 50 may train the electrical reliability properties prediction model by using predicted electrical reliability property data as an output value and the data set on which the data pre-processing has been performed, as an input value, and may predict, based on a plurality of pieces of target optical data, electrical reliability properties of defects of the substrate. Here, the electrical reliability properties prediction model of the electrical reliability properties prediction module 50 may extract feature vectors from the plurality of pieces of target optical data and detect predicted electrical reliability property data of the plurality of pieces of target optical data based on the feature vectors. Electrical reliability properties of defects of the substrate may be predicted based on the predicted electrical reliability property data. The plurality of pieces of target optical data may be spectrum data, such as the plurality of pieces of optical spectrum data.

In exemplary embodiments of the present invention, reliability properties may include whether a semiconductor device exhibits defects and its operational lifespan. Typically, Vramp or TDDB (time dependent dielectric breakdown) measurements of semiconductor devices are conducted to assess their electrical reliability properties. For instance, the Vramp test typically involves subjecting a semiconductor device to a specific voltage variation and subsequently measuring its current or other electrical parameters. Through the Vramp test, the reliability of semiconductor devices, including defect detection and lifespan estimation, can be effectively evaluated.

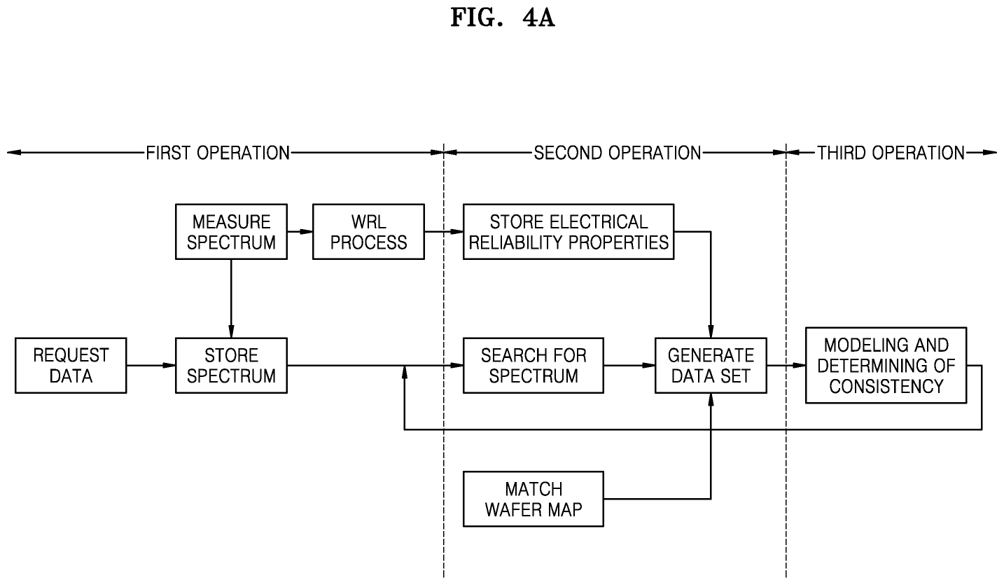

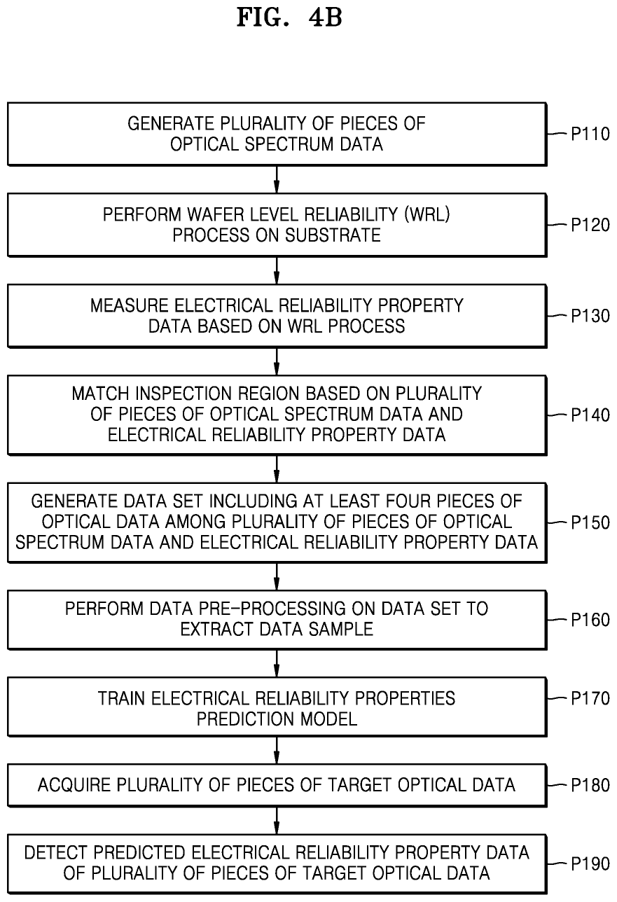

FIGS. 4A and 4B are flowcharts of an electrical reliability properties prediction method according to an embodiment. The embodiments of FIGS. 4A and 4B will be described also by referring to FIGS. 1 and 3, and description of the details provided above with reference to FIGS. 1 and 3 is briefly provided or omitted.

Referring to FIGS. 4A and 4B, in the electric reliability properties prediction method according to some embodiments, the server 20 may request in advance from the database 10 and the substrate inspection device 100 set-up data for predicting defects. The substrate inspection device 100 may acquire a spectral image upon the request of the server 20 and extract a plurality of pieces of optical spectrum data from the spectral image. The plurality of pieces of optical spectrum data may include optical critical dimension data of the substrate. The optical critical dimension data may be acquired by the substrate inspection device 100.

In the electrical reliability properties prediction method according to some embodiments, first, a plurality of pieces of optical spectrum data of a substrate may be generated in operation P110. At the request of the server 20, the substrate inspection device 100 may generate a plurality of pieces of optical spectrum data. The substrate inspection device 100 may transmit the generated plurality of pieces of optical spectrum data to the server 20 and the database 10. The database 10 may store the generated plurality of pieces of optical spectrum data.

After generating the plurality of pieces of optical spectrum data, a wafer level reliability (WLR) process may be performed on the substrate in operation P120. The WLR process may be a test process for selecting a good product or a defective product by examining electrical reliability properties of the substrate. Here, electrical reliability property data of the substrate may be measured based on the WLR process in operation P130. The electrical reliability property data may be data indicating whether or not the substrate has electrical defects in shot units. Here, the database 10 may store the electrical reliability property data. After that, operations P140 to P180 will be described with reference to the remaining drawings.

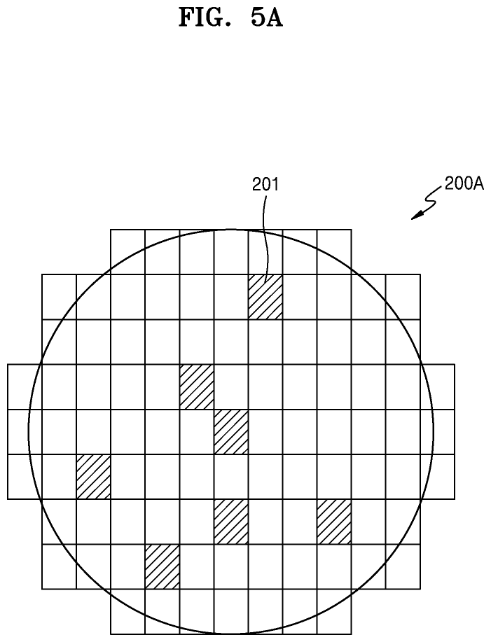

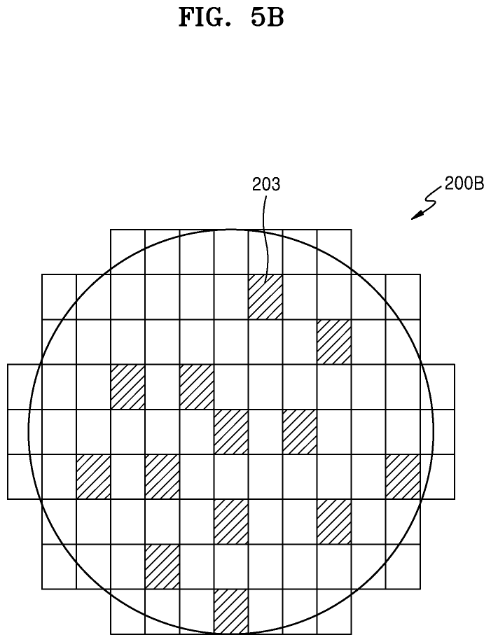

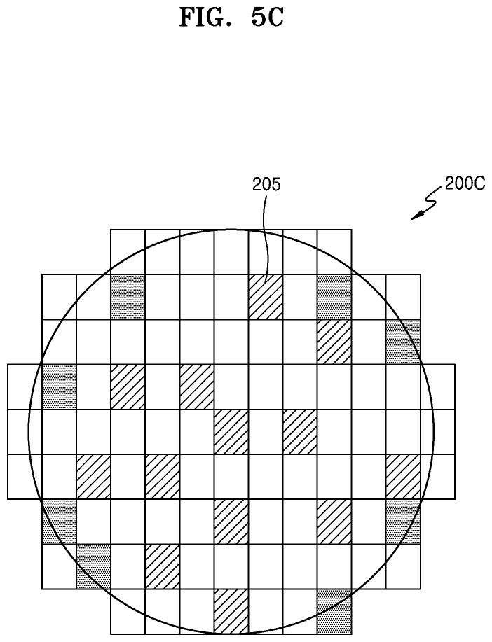

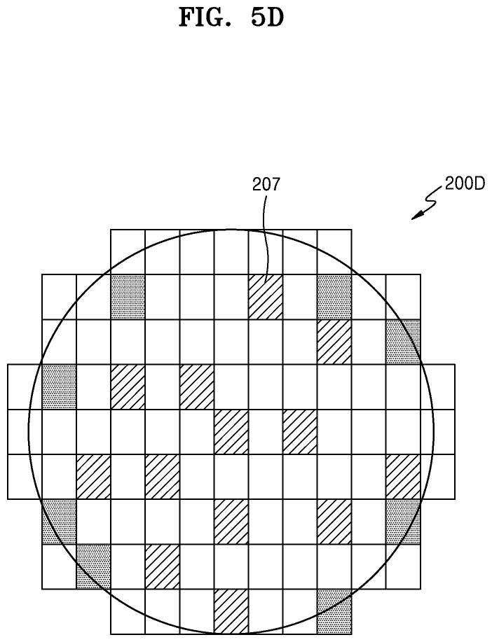

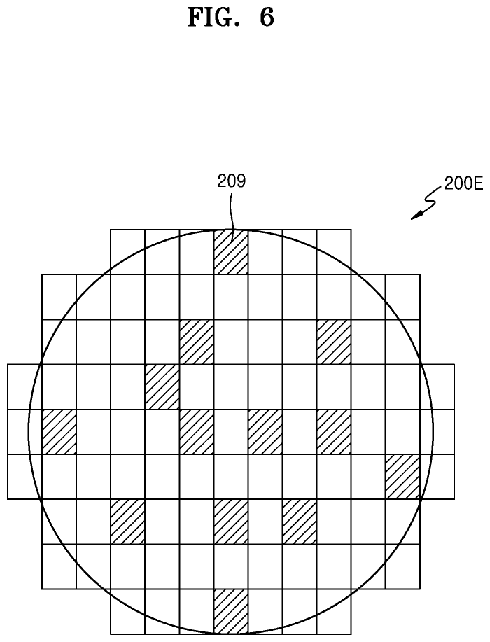

FIGS. 5A to 5D are diagrams illustrating measurement regions of optical data according to embodiments. FIG. 6 is a diagram showing electrical reliability property data of a substrate according to an embodiment.

Referring to FIGS. 5A to 5D, FIG. 5A illustrates a plurality of first measurement regions 201 of a plurality of pieces of optical spectrum data of a substrate 200A at a first point in time. FIG. 5B illustrates a plurality of second measurement regions 203 of a plurality of pieces of optical spectrum data of a substrate 200B at a second point in time. FIG. 5C illustrates a plurality of third measurement regions 205 of a plurality of pieces of optical spectrum data of a substrate 200C at a third point in time. FIG. 5D illustrates a plurality of fourth measurement regions 207 of a plurality of pieces of optical spectrum data of a substrate 200D at a fourth point in time. FIG. 6 illustrates a plurality of fifth measurement regions 209 of electrical reliability property data of a substrate 200E at a fifth point in time. Here, the first to fourth points in time may include different points in time during a semiconductor process for forming a pattern in a substrate. Also, the first to fifth measurement regions 201, 203, 205, 207, and 209 may be chip-unit regions of the substrate.

In embodiments, the first point in time may be any one point in time during a semiconductor process of forming an active region in the substrate 200A; the second point in time may be any one point in time during a semiconductor process of forming a dummy gate in the substrate 200D; the third point in time may be any one point in a semiconductor process of forming a source region and/or a drain region; the fourth point in time may be any one point in time of a semiconductor process of forming a contact between a front end of line (FEOL) structure and a back end of line (BEOL) structure. Here, the plurality of pieces of optical spectrum data may include a plurality of pieces of optical spectrum data measured at different points in time (e.g., the first to fourth points in time).

After measuring the electrical reliability property data, the data matching unit 30 may match an inspection region to the plurality of pieces of optical spectrum data and the electrical reliability property data based on the plurality of pieces of optical spectrum data and the electrical reliability property data in operation P140. In detail, in the matching of the inspection region, first, an overlapping region between the first to fourth measurement regions of the plurality of pieces of optical spectrum data and the fifth measurement region of the electrical reliability property data may be determined. In operation P140, at least four of the plurality of pieces of optical spectrum data may be used. A reference measurement region here may be the fifth measurement region of the electrical reliability property data. Next, in the matching of the inspection region, the plurality of pieces of optical spectrum data and the electrical reliability property data may be extracted based on the overlapping region. In detail, based on the overlapping region, except for some pieces of optical spectrum data of some measurement regions among the plurality of pieces of optical spectrum data, pieces of optical spectrum data of the remaining measurement regions among the plurality of pieces of optical spectrum data may be matched to the electrical reliability property data.

The data matching unit 30 may determine the measurement size of each of measurement regions of the plurality of pieces of optical spectrum data and a measurement region of the electrical reliability property data and/or the number of measurement regions based on the overlapping region. Also, the data matching unit 30 may match a substrate map corresponding to the inspection region to the plurality of pieces of optical spectrum data and the electrical reliability property data. That is, the plurality of pieces of optical spectrum data, the electrical reliability property data, and the substrate map corresponding to the inspection region may be matched to one another and stored. A data set to be described below may include the substrate map corresponding to the inspection region, and the electrical reliability properties prediction module 50 may predict electrical reliability property data based on the data set including the substrate map corresponding to the inspection region.

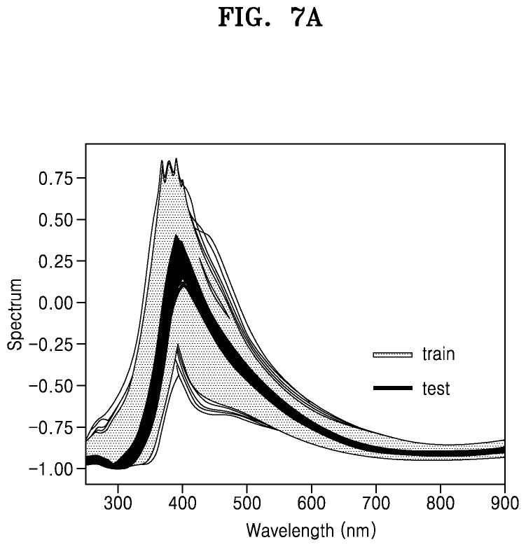

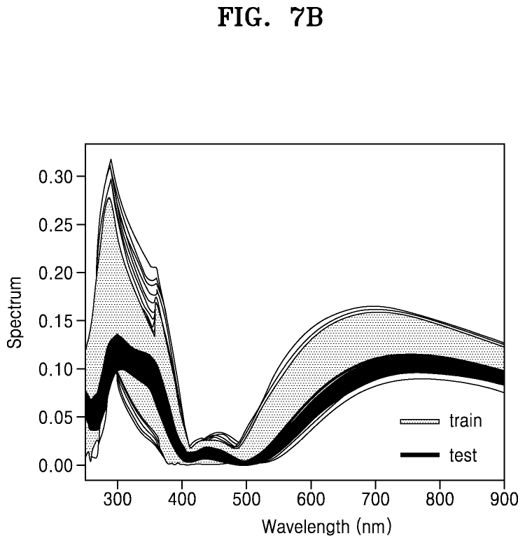

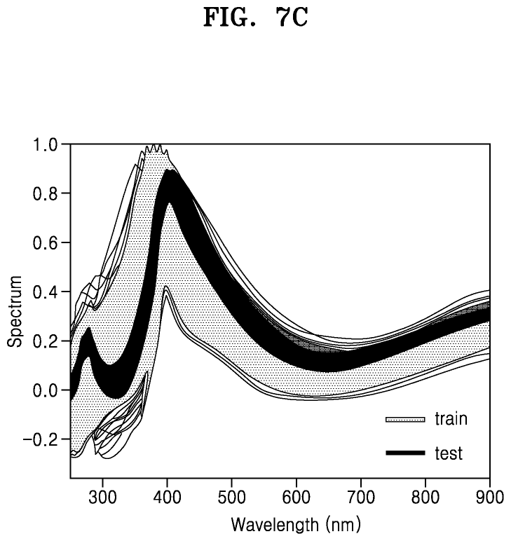

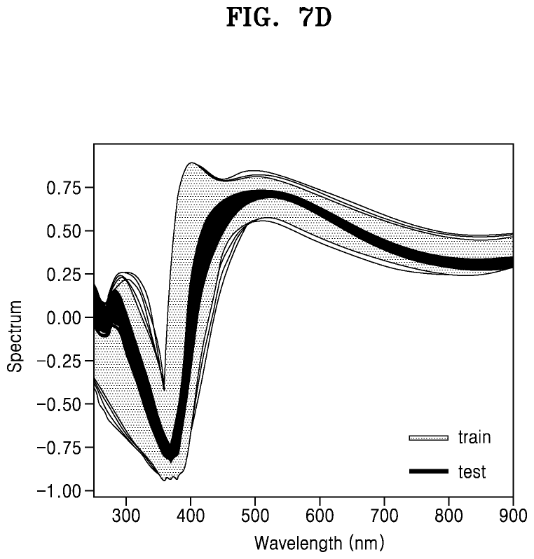

FIGS. 7A to 7D are graphs showing optical data according to embodiments. The embodiments of FIGS. 7A to 7D will be described also by referring to FIGS. 1 to 6, and description of the details provided above with reference to FIGS. 1 to 6 is briefly provided or omitted.

FIG. 7A is a graph showing a plurality of pieces of optical spectrum data of the first point in time. FIG. 7B is a graph showing a plurality of pieces of optical spectrum data of the second point in time. FIG. 7C is a graph showing a plurality of pieces of optical spectrum data of the third point in time. FIG. 7D is a graph showing a plurality of pieces of optical spectrum data of the fourth point in time. In the graphs of FIGS. 7A to 7D, the horizontal axis represents the wavelength and the vertical axis represents the spectrum value.

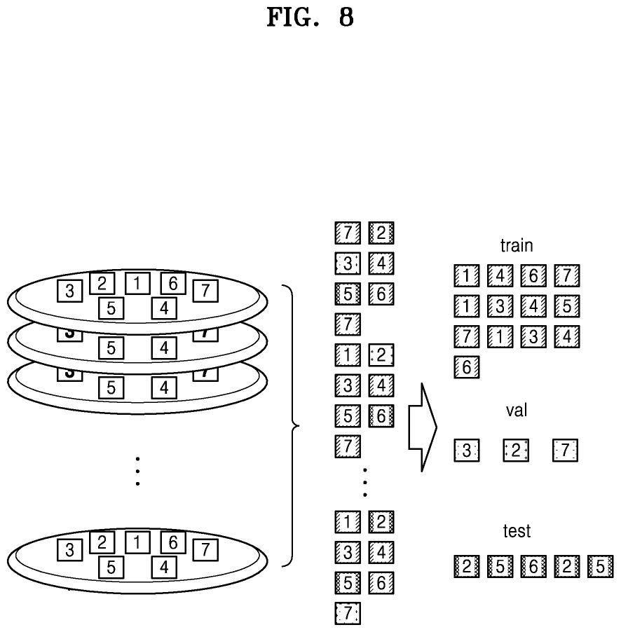

Referring to FIGS. 7A to 7D, after matching between the optical spectrum data and the electrical reliability property data, a data set including at least four pieces of optical data among the plurality of pieces of optical spectrum data and electrical reliability property data may be generated by the data matching unit 30 in operation P150. The data set may include a plurality of pieces of optical spectrum data and electrical reliability property data of a same substrate and at a same point. The at least four pieces of optical data may be data of different points in time (e.g., the first to fourth points in time). Although the optical spectrum data in the graphs of FIGS. 7A to 7D are shown to be classified into a learning data set (train) and a test data set (test), respectively, a verification data set may also be classified together. The data classification method will be described below with reference to FIG. 8.

The spectral data presented in FIGS. 7A to 7D represents the raw optical spectrum data corresponding to semiconductor devices on the provided wafer. As the wafer undergoes different processes at various time points (first, second, third, and fourth point in time), the patterns on it may vary in shape and material composition. Consequently, the optical spectrum measurements may differ based on the pattern shape, materials present, and their composition ratios. Thus, the optical spectrum measurements at each time point (first, second, third, and fourth point in time) may exhibit variations from one another.

FIG. 8 is a conceptual diagram illustrating a data classification method of an electrical reliability properties prediction method, according to an embodiment. The embodiment of FIG. 8 will be described also by referring to FIGS. 1 to 6, and description of the details provided above with reference to FIGS. 1 to 6 is briefly provided or omitted.

Referring to FIG. 8, after generating the data set, the data pre-processing unit 40 may perform data pre-processing on the data set to extract a data sample in operation P160. In detail, in the data pre-processing, first, the data set may be classified into a learning data set (train), a verification data set (val), and a test data set (test). Each of the learning data set, the verification data set, and the test data set may include at least four pieces of optical data and electrical reliability property data. Here, the data pre-processing unit 40 may classify the data set by using random sampling. Each of the learning data set, the verification data set, and the test data set may be classified in a certain ratio. In embodiments, the largest number of data sets may be classified as a learning data set. Also, a greater ratio of the remaining data sets may be classified as a verification data set than as a test data set.

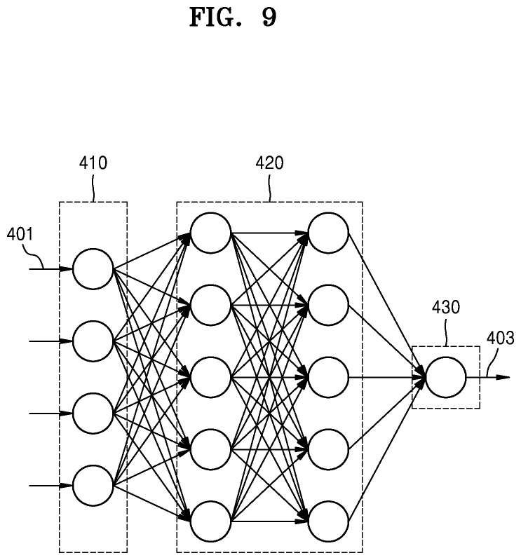

FIG. 9 is a conceptual diagram for describing an electrical reliability properties prediction model according to an embodiment. The embodiment of FIG. 9 will be described also by referring to FIGS. 1 to 6, and description of the details provided above with reference to FIGS. 1 to 6 is briefly provided or omitted.

Referring to FIG. 9, after classifying the data set, by using the electrical reliability properties prediction module 50, the electrical reliability properties prediction model may be trained by using the predicted electrical reliability property data as an output value and the data set on which the data pre-processing was performed, as an input value, in operation P170. Here, the electrical reliability properties prediction model may be trained using an artificial neural network learning method of Feed-Forward Neural Networks (FFNN).

The electrical reliability properties prediction model may include an input layer 410 with input 401, a plurality of hidden layers 420, and an output layer 430. The input layer 410 may receive input data (e.g., a data set on which data pre-processing is performed) as an input value. The plurality of hidden layers 420 are layers positioned between the input layer 410 and the output layer 430 and may be composed of a series of neurons. Each neuron may accept an input value and output a result of applying an activation function. The activation function may adjust an output value of the neuron. The output layer 430 may be a layer that outputs a final output value 403. The output layer 430 may output predicted electrical reliability property data and/or target predicted electrical reliability property data. Weights and biases of the electrical reliability properties prediction model may be adjusted based on a backpropagation algorithm.

In detail, training may be performed based on the classified learning data set, the electrical reliability properties prediction model on which the training has been performed may be verified using the verification data set, and the electrical reliability properties prediction model may be evaluated based on the test data set.

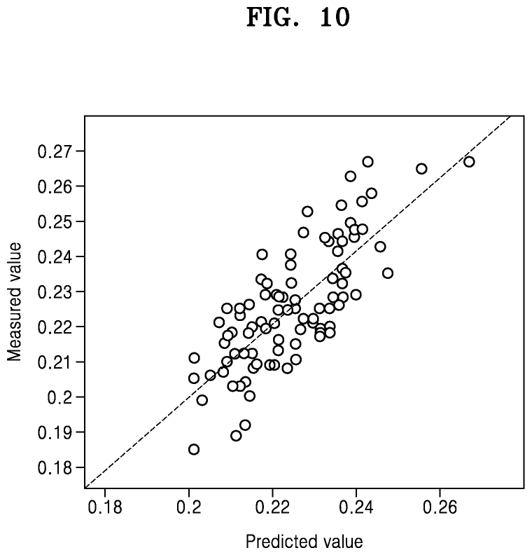

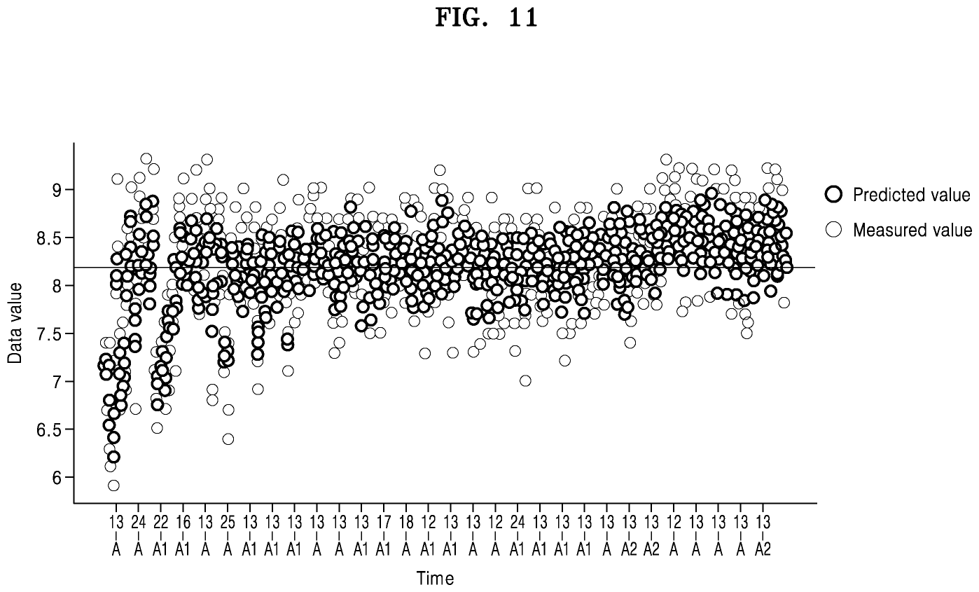

FIG. 10 is a graph showing the consistency of an electrical reliability properties prediction model according to an embodiment. FIG. 11 is a graph showing effects of an electrical reliability properties prediction device and an electrical reliability properties prediction method, according to an embodiment.

Referring to FIGS. 10 and 11, the horizontal axis represents predicted electrical reliability property data and the vertical axis represents actually measured electrical reliability property data. The consistency of the electrical reliability properties prediction model may be determined by comparing the predicted electrical reliability property data, which is an output value of the electrical reliability properties prediction model, with the measured electrical reliability property data. When the consistency of the electrical reliability properties prediction model is lower than a preset threshold, the electrical reliability properties prediction model may be re-trained based on a data set that is different from the data set. Here, the different data set may refer to a data set that is different from the data set used for first training and stored in a database. When the consistency of the electric reliability properties prediction model is greater than or equal to a preset threshold value, the predicted electric reliability property data of the plurality of pieces of target optical data may be detected. The preset threshold may be in a range of about 0.5 to about 0.9. As described above, by determining the consistency with respect to the electrical reliability properties prediction model and forming an excellent electrical reliability properties prediction model, as shown in FIG. 11, a tendency that a predicted value of the electrical reliability properties of a substrate (Predicted value) corresponds to a measured value of the actual electrical reliability property data (Measured value) was confirmed.

Through the server 20, the electrical reliability properties prediction module 50 may acquire a plurality of pieces of target optical data from the database in operation P180. The plurality of pieces of target optical data may include optical spectrum data of the substrate before the WLR process is performed. Here, the plurality of pieces of target optical data may be acquired, and a target data set including at least four pieces of target optical data among the plurality of pieces of target optical data may be generated.

After acquiring the plurality of pieces of target optical data, by using the electrical reliability properties prediction module 50, a feature vector may be extracted from the plurality of pieces of target optical data using the electrical reliability properties prediction model, with respect to the plurality of pieces of target optical data. Here, the feature vector may refer to features extracted to represent a plurality of pieces of target optical data and made into a single vector. Also, predicted electrical reliability property data of the plurality of pieces of target optical data may be detected based on the feature vector by the electrical reliability properties prediction module 50 in operation P190. The electrical reliability properties prediction model may receive the plurality of pieces of target optical data as inputs and perform learning by passing through several layers of an artificial neural network, and finally predict predicted electrical reliability property data for the plurality of pieces of target optical data. Accordingly, electrical reliability properties of defects of patterns formed in a substrate may be predicted before performing an electrical reliability property test such as a WLR process. Reliability of a semiconductor device may be improved by predicting electrical reliability properties of substrate defects in advance.

Typically, the reliability properties of semiconductor components are determined by directly measuring Vramp after the completion of the semiconductor fabrication process. Typically, the reliability properties of semiconductor components can be assessed after their fabrication is complete. Therefore, if improvements in semiconductor components are made based on the results of these typical reliability properties measurements, delays in semiconductor process development may occur because improvements are made after the semiconductor components are completed.

One exemplary embodiment of the present invention, an electrical reliability prediction method, predicts information about electrical reliability properties from optical spectrum data obtained as each stage of the semiconductor fabrication process is completed. Therefore, compared to the improvement process after typical measurement of the reliability properties of semiconductor components, according to one exemplary embodiment of the present invention, electrical reliability prediction methods allow for prediction of electrical outdoor characteristics before semiconductor components are completed. For example, as electrical reliability properties prediction can be made approximately two months earlier than with typical methods, improvements in processes can be facilitated earlier by one exemplary embodiment of the present invention, compared to typical methods.

Various changes in form and details may be made therein without departing from the spirit and scope of the following claims.

What is claimed is:

1. An electrical reliability properties prediction method comprising:
generating a plurality of pieces of optical spectrum data of a substrate;
performing a wafer level reliability (WLR) process on the substrate;
measuring electrical reliability property data based on the WLR process;
matching an inspection region to the plurality of pieces of optical spectrum data and the electrical reliability property data based on the plurality of pieces of optical spectrum data and the electrical reliability property data;
generating a data set comprising at least four pieces of optical data among the plurality of pieces of optical spectrum data and the electrical reliability property data;
performing data pre-processing on the data set to extract a data sample;
training an electrical reliability properties prediction model by using predicted electrical reliability property data as an output value and the data sample, as an input value;
acquiring a plurality of pieces of target optical data from a database; and
extracting, with respect to the plurality of pieces of target optical data, a feature vector from the plurality of pieces of target optical data by using the electrical reliability properties prediction model, and detecting predicted electrical reliability property data of the plurality of pieces of target optical data based on the feature vector.

2. The electrical reliability properties prediction method of claim 1, wherein the performing data pre-processing comprises classifying the data set into a learning data set, a verification data set, and a test data set.

3. The electrical reliability properties prediction method of claim 2, wherein the training of the electrical reliability properties prediction model comprises:
performing training of the electrical reliability properties prediction model based on the learning data set;
verifying the electrical reliability properties prediction model on which the training has been performed, by using the verification data set; and
evaluating the electrical reliability properties prediction model based on the test data set.

4. The electrical reliability properties prediction method of claim 1, wherein the electrical reliability properties prediction model uses a neural network learning method of Feed-Forward Neural Networks (FFNN).

5. The electrical reliability properties prediction method of claim 1, wherein each of the plurality of pieces of optical spectrum data comprises optical critical dimension data extracted from a spectral image of the substrate.

6. The electrical reliability properties prediction method of claim 1, wherein the matching of the inspection region based on the plurality of pieces of optical spectrum data and the electrical reliability property data comprises:
determining an overlapping region between measurement regions of the plurality of pieces of optical spectrum data and a measurement region of the electrical reliability property data, and
extracting the plurality of pieces of optical spectrum data and the electrical reliability property data based on the overlapping region.

7. The electrical reliability properties prediction method of claim 6, wherein the matching of the inspection region based on the plurality of pieces of optical spectrum data and the electrical reliability property data comprises determining a measurement size of each of the measurement regions of the plurality of pieces of optical spectrum data and the measurement region of the electrical reliability property data based on the overlapping region.

8. The electrical reliability properties prediction method of claim 1, wherein the training of the electrical reliability properties prediction model further comprises determining a consistency of the electrical reliability properties prediction model by comparing the predicted electrical reliability property data, which is the output value of the electrical reliability properties prediction model, with measured electrical reliability property data.

9. The electrical reliability properties prediction method of claim 8, wherein the determining of the consistency of the electrical reliability properties prediction model comprises re-training the electrical reliability properties prediction model based on the data set and other data sets stored in the database when the consistency of the electrical reliability properties prediction model is lower than a preset threshold.

10. The electrical reliability properties prediction method of claim 1, wherein the matching of the inspection region based on the plurality of pieces of optical spectrum data and the electrical reliability property data comprises matching a substrate map corresponding to the inspection region with the plurality of pieces of optical spectrum data and the electrical reliability property data.

11. An electrical reliability properties prediction method comprising:
requesting optical data from a server;
acquiring a spectral image of a substrate based on the requesting, and extracting a plurality of pieces of optical spectrum data from the spectral image;
performing a wafer level reliability (WLR) process on the substrate;
measuring electrical reliability property data based on the WLR process;
matching an inspection region to the plurality of pieces of optical spectrum data and the electrical reliability property data based on the plurality of pieces of optical spectrum data and the electrical reliability property data;
generating a data set comprising at least four pieces of optical data among the plurality of pieces of optical spectrum data and the electrical reliability property data;
performing data pre-processing on the data set to obtain a data sample;
training an electrical reliability properties prediction model by using predicted electrical reliability property data as an output value and the data sample, as an input value;
acquiring a plurality of pieces of target optical data from a database; and
extracting, with respect to the plurality of pieces of target optical data, a feature vector from the plurality of pieces of target optical data by using the electrical reliability properties prediction model, and detecting predicted electrical reliability property data of the plurality of pieces of target optical data based on the feature vector,
wherein the electrical reliability properties prediction model uses a neural network learning method of Feed-Forward Neural Networks (FFNN).

12. The electrical reliability properties prediction method of claim 11, wherein the performing data pre-processing comprises classifying the data set into a learning data set, a validation data set, and a test data set, wherein the classifying of the data set comprises classifying the data set by using random sampling.

13. The electrical reliability properties prediction method of claim 12, wherein the training of the electrical reliability properties prediction model comprises:
performing training of the electrical reliability properties prediction model based on the learning data set;
verifying the electrical reliability properties prediction model on which the training has been performed, by using a verification data set;
evaluating the electrical reliability properties prediction model based on the test data set; and
determining a consistency of the electrical reliability properties prediction model by comparing the predicted electrical reliability property data, which is the output value of the electrical reliability properties prediction model, with measured electrical reliability property data measured through the WLR process.

14. The electrical reliability properties prediction method of claim 13, wherein the determining of the consistency of the electrical reliability properties prediction model comprises, when the consistency of the electrical reliability properties prediction model is lower than a preset threshold value, re-training the electrical reliability properties prediction model based on a second data set that is different from the data set, and detecting the predicted electrical reliability property data for the plurality of pieces of target optical data when the consistency of the electrical reliability properties prediction model is equal to or greater than the preset threshold value.

15. The electrical reliability properties prediction method of claim 11, wherein the acquiring of the plurality of pieces of target optical data from the database comprises generating a target data set comprising at least four pieces of target optical data from among the plurality of pieces of target optical data.

16. The electrical reliability properties prediction method of claim 15, wherein the electrical reliability properties prediction model detects the predicted electrical reliability property data with respect to the target data set.

17. An electrical reliability properties prediction device comprising:
a substrate inspection device configured to acquire a spectral image of a substrate according to a request from a server and extract a plurality of pieces of optical spectrum data from the spectral image;
a database configured to store a plurality of pieces of target optical data, the plurality of pieces of optical spectrum data, and electrical reliability property data of the substrate;
the server configured to store a program comprising one or more instructions and executing the one or more instructions of the program;
a data matching unit configured to match an inspection region to the plurality of pieces of optical spectrum data and the electrical reliability property data based on the plurality of pieces of optical spectrum data and the electrical reliability property data and generate a data set comprising at least four pieces of optical data among the plurality of pieces of optical spectrum data and the electrical reliability property data;
a data pre-processing unit configured to perform data pre-processing on the data set; and
an electrical reliability properties prediction module configured to train an electrical reliability properties prediction model by using predicted electrical reliability property data as an output value and the data set on which the data pre-processing has been performed, as an input value, and predict, based on the plurality of pieces of target optical data, electrical reliability for defects of the substrate.

18. The electrical reliability properties prediction device of claim 17, wherein the electrical reliability properties prediction module is configured to extract, with respect to the plurality of pieces of target optical data, a feature vector from the plurality of pieces of target optical data by using the electrical reliability properties prediction model and obtains the predicted electrical reliability property data of the plurality of pieces of target optical data based on the feature vector.

19. The electrical reliability properties prediction device of claim 17, wherein the substrate inspection device comprises:
a light source configured to emit unpolarized incident light to the substrate;
a polarizer disposed on a first path of the incident light between the light source and the substrate and linearly polarizes the incident light;
a first compensator disposed on a second path of the incident light between the polarizer and the substrate;
a light splitting element configured to receive reflected light, which is light reflected by the substrate, and split the reflected light into first split light and second split light;
a second compensator disposed on a third path of the reflected light between the substrate and the light splitting element;
an analyzer disposed on a fourth path of the reflected light between the second compensator and the light splitting element;
a first detector configured to detect the first split light and a second detector configured to detect the second split light;
a controller configured to control the first detector and the second detector; and
a processor configured to process signals detected by the first detector and the second detector.

20. The electrical reliability properties prediction device of claim 17, wherein the server is configured to:
determine consistency of the electrical reliability properties prediction model of the electrical reliability properties prediction module,
retrain the electrical reliability properties prediction model based on a second data set that is different from the data set when the consistency of the electrical reliability properties prediction model is lower than a preset threshold value, and
instruct the electrical reliability properties prediction module to detect the predicted electrical reliability property data for the plurality of pieces of target optical data when the consistency of the electrical reliability properties prediction model is equal to or greater than the preset threshold value.
